(19) United States
(12) Patent Application Publication
(10) Pub. No.: US 2024/0355889 A1
(43) Pub. Date: Oct. 24, 2024

(54) SEMICONDUCTOR DEVICE

(71) Applicant: ROHM CO., LTD., Kyoto-shi (JP)

(72) Inventor: Junya FUKUNISHI, Kyoto-shi (JP)

(73) Assignee: ROHM CO., LTD., Kyoto-shi (JP)

(21) Appl. No.: 18/761,637

(22) Filed: Jul. 2, 2024

Related U.S. Application Data
(63) Continuation of application No. PCT/JP2022/040078, filed on Oct. 27, 2022.

(30) Foreign Application Priority Data
Jan. 11, 2022 (JP) 2022-002323

(51) Int. Cl. H01L 29/40; H01L 29/06; H01L 29/417; H01L 29/78

(52) U.S. Cl. CPC H01L 29/407; H01L 29/0696; H01L 29/41741; H01L 29/7813

(57) ABSTRACT

A semiconductor device includes: a semiconductor layer; a gate trench formed in the semiconductor layer, the gate trench extending in a first direction in plan view; an insulation layer formed on the semiconductor layer; a field plate electrode arranged in the gate trench and having a width in the second direction; and a gate electrode arranged in the gate trench and separated from the field plate electrode by the insulation layer. The gate trench includes a first region in which the gate electrode is located above the field plate electrode in a depth-wise direction of the gate trench, and a second region including an end of the gate trench in the first direction. The field plate electrode in the second region includes a widened portion having a width that is greater than a width of the field plate electrode in the first region.

### CROSS-REFERENCE TO RELATED APPLICATIONS

The present application is a bypass continuation of International Patent Application No. PCT/JP2022/040078, filed on Oct. 27, 2022, which claims priority to Japanese Patent Application No. 2022-002323, filed on Jan. 11, 2022, the entire disclosures of these applications are incorporated herein by reference.

### BACKGROUND

### 1. Field

The present disclosure relates to a semiconductor device.

### 2. Description of Related Art

Japanese Laid-Open Patent Publication No. 2018-129378 discloses a metal insulator semiconductor field effect transistor (MISFET) having a split-gate structure.

The split-gate structure disclosed in Japanese Laid-Open Patent Publication No. 2018-129378 includes a gate trench formed in a semiconductor layer, an embedded electrode embedded in a bottom portion of the gate trench as a field plate electrode, and a gate electrode embedded in an upper portion of the gate trench. The gate electrode and the field plate electrode in the gate trench are separated from each other by an insulating layer.

### BRIEF DESCRIPTION OF THE DRAWINGS

FIG. 1 is a schematic top view of an exemplary semiconductor device in accordance with a first embodiment.

FIG. 2 is a schematic cross-sectional view of the semiconductor device taken along line F2-F2 in FIG. 1.

FIG. 3 is a schematic cross-sectional view of the semiconductor device taken along line F3-F3 in FIG. 1.

FIG. 4 is an enlarged plan view of the semiconductor device shown in FIG. 1.

FIG. 5 is a schematic cross-sectional view of the semiconductor device taken along line F5-F5 in FIG. 4.

FIG. 6 is a schematic cross-sectional view of the semiconductor device taken along line F6-F6 in FIG. 4.

FIG. 7 is an enlarged plan view of a semiconductor device in accordance with a modified example of the first embodiment.

FIG. 8 is a schematic cross-sectional view of the semiconductor device taken along line F8-F8 in FIG. 7.

FIG. 9 is an enlarged plan view of a semiconductor device in accordance with a second embodiment.

FIG. 10 is a schematic cross-sectional view of the semiconductor device taken along line F10-F10 in FIG. 9.

FIG. 11 is an enlarged plan view of a semiconductor device in accordance with a modified example of the second embodiment.

FIG. 12 is a schematic cross-sectional view of a semiconductor device illustrating a modified example of a cross-sectional shape of a field plate electrode in a first region.

FIG. 13 is a schematic cross-sectional view of the semiconductor device shown in FIG. 12 in a second region.

### DETAILED DESCRIPTION

Embodiments of a semiconductor device in accordance with the present disclosure will now be described with reference to the accompanying drawings. Elements in the drawings are illustrated for simplicity and clarity and are not necessarily drawn to scale. To facilitate understanding, hatching lines may not be shown in the cross-sectional drawings. The accompanying drawings merely illustrate exemplary embodiments in accordance with the present disclosure and are not intended to limit the present disclosure.

The detailed description below includes devices, systems, and/or methods that are exemplary embodiments of the present disclosure. This detailed description is merely illustrative and is not intended to limit embodiments of the present disclosure or application and use of the embodiments.

### First Embodiment

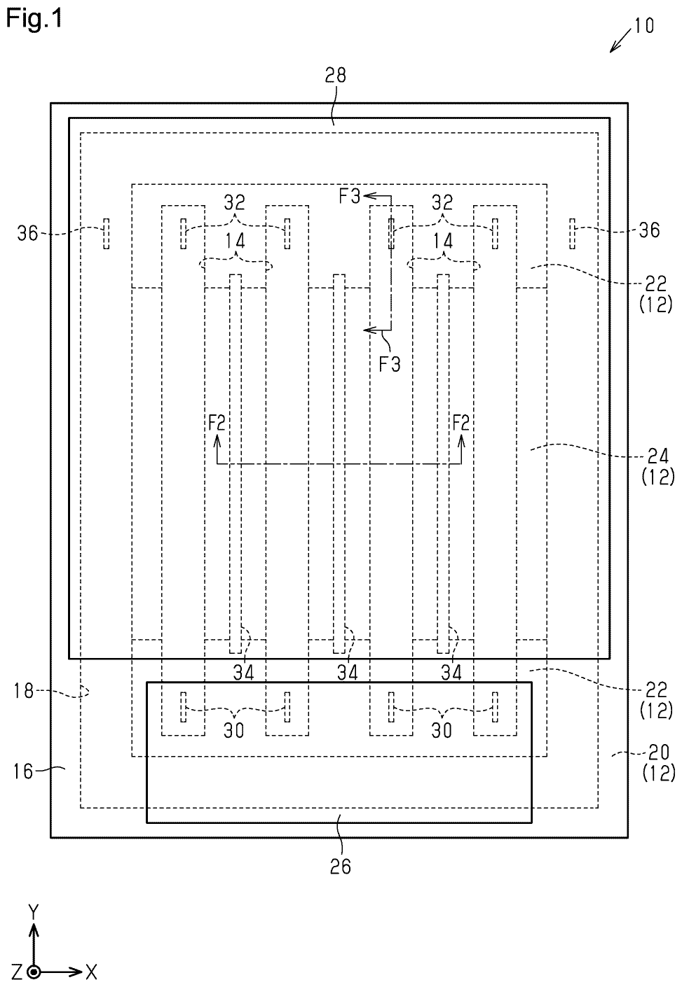

FIG. 1 is a schematic top view of an exemplary semiconductor device 10 in accordance with a first embodiment. In this disclosure, the X-axis, Y-axis, and Z-axis are orthogonal to one another as shown in FIG. 1. The term “plan view” as used in this specification is a view of the semiconductor device 10 taken in the Z-direction. Unless otherwise indicated, the term “plan view” will refer to a view taken from above along the Z-axis of the semiconductor device 10.

The semiconductor device 10 is, for example, a MISFET having a split-gate structure. The semiconductor device 10 includes a semiconductor layer 12, a gate trench 14 formed in the semiconductor layer 12, and an insulation layer 16 formed on the semiconductor layer 12.

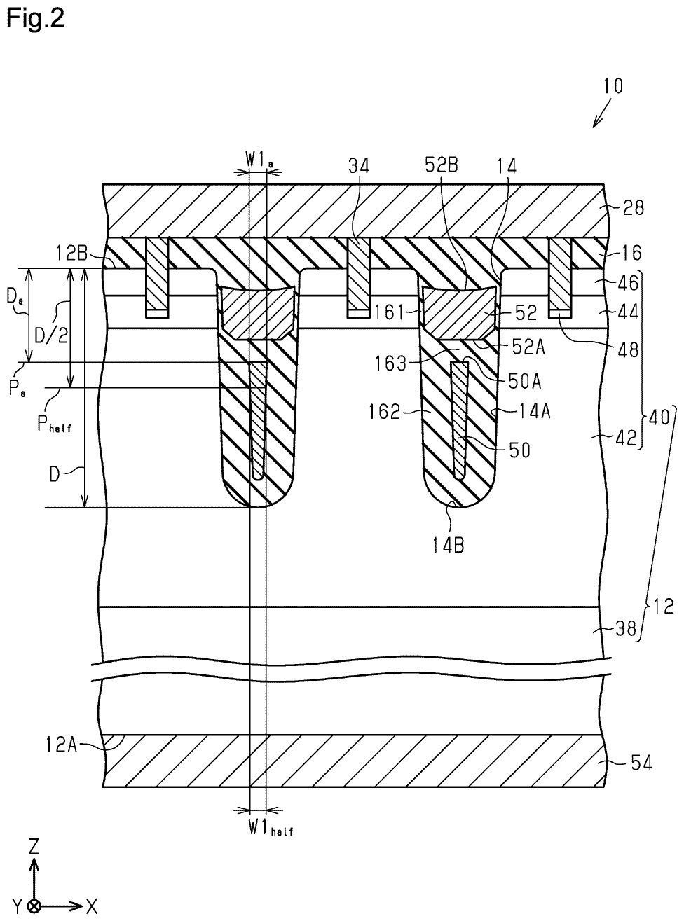

In an example, the semiconductor layer 12 may be formed from silicon (Si). The semiconductor layer 12 includes a first surface 12A and a second surface 12B at a side opposite to the first surface 12A (refer to FIG. 2). Further, the semiconductor layer 12 has a thickness in a direction (Z-direction) orthogonal to the first surface 12A. The second surface 12B of the semiconductor layer 12 is adjacent to the insulation layer 16.

The gate trench 14 includes an opening in the second surface 12B of the semiconductor layer 12 and has a depth in the Z-direction. Further, the gate trench 14 extends in the Y-direction in plan view and has a width in the X-direction. In the present specification, the Z-direction may also be referred to as “depth-wise direction of the gate trench 14”, the Y-direction may also be referred to as “first direction”, and the X-direction may also be referred to as “second direction”. Therefore, the depth-wise direction of the gate trench 14 is orthogonal to both of the first direction and the second direction. The second direction is orthogonal to the first direction in plan view.

The gate trench 14 may be one of a plurality of gate trenches 14 formed in the semiconductor layer 12. The gate trenches 14 (four gate trenches 14 in example in FIG. 1) may be arranged in a striped array. In an example, the gate trenches 14 may be arranged in the X-direction at equal intervals in plan view. A field plate electrode 50 and a gate electrode 52, which will be described later with reference to FIG. 2, may be arranged in each gate trench 14.

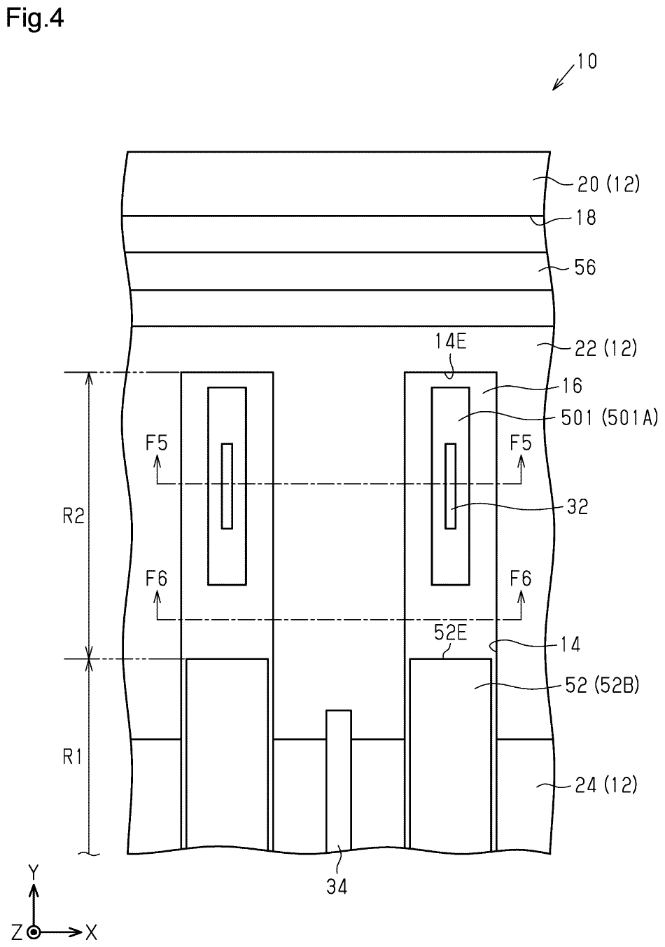

The semiconductor device 10 may further include a peripheral trench 18 formed in the semiconductor layer 12. The peripheral trench 18 may surround the gate trenches 14 while being separated from the gate trenches 14 in plan view. A peripheral electrode 56, which will be described later with reference to FIG. 4, may be arranged in the peripheral trench 18.

As shown in FIG. 1, the second surface 12B of the semiconductor layer 12 may include an n⁺-type region 20 including an n-type impurity, a p⁻-type region 22 including a p-type impurity, and an n⁺-type region 24 including an n-type impurity. The n-type region 20 may surround peripheral trench 18. Further, the peripheral trench 18 may surround the p⁻-type region 22 and the n⁺-type region 24. The peripheral trench 18 does not expose a pn junction interface between the p⁻-type region 22 and the n⁺-type region 24, thereby increasing the breakdown voltage of the semiconductor device 10.

Each gate trench 14 may be arranged adjacent to both of the p⁻-type region 22 and the n⁺-type region 24. In the example shown in FIG. 1, the n⁺-type region 24 may be located between two p⁻-type regions 22 in the Y-direction. The gate trench 14 may be adjacent to one of the two p⁻-type regions 22 at each end in the Y-direction, and may be adjacent to the n⁺-type region 24 at an intermediate portion.

The semiconductor device 10 may further include a gate interconnection 26 and a source interconnection 28 that are formed on the insulation layer 16. Each of the gate interconnection 26 and the source interconnection 28 may be arranged to cover part of the gate trench 14 and part of the peripheral trench 18. The gate interconnection 26 may be arranged to at least partially overlap one of the two p⁻-type regions 22. The source interconnection 28 may be arranged to at least partially overlap the other one of the two p⁻-type regions 22. The source interconnection 28 may cover at least the entire n⁺-type region 24 while being separated from the gate interconnection 26.

The gate interconnection 26 and the source interconnection 28 may be formed from at least one of titanium (Ti), nickel (Ni), gold (Au), silver (Ag), copper (Cu), aluminum (Al), a Cu alloy, and an Al alloy.

The semiconductor device 10 may further include gate contacts 30. Each gate contact 30 may connect the gate electrode 52 (refer to FIG. 2) arranged in a corresponding gate trench 14 to the gate interconnection 26. The gate contact 30 may extend through the insulation layer 16 located between the gate electrode 52 and the gate interconnection 26 in the Z-direction. The gate contact 30 may be arranged in a region where the gate interconnection 26 overlaps the gate trench 14 in plan view.

The semiconductor device 10 may further include source contacts 32. Each source contact 32 may connect the field plate electrode 50 (refer to FIG. 2) arranged in a corresponding gate trench 14 to the source interconnection 28. The source contact 32 may extend through the insulation layer 16 located between the field plate electrode 50 and the source interconnection 28 in the Z-direction. The source contact 32 may be arranged in a region where the source interconnection 28 overlaps the gate trench 14 in plan view.

The semiconductor device 10 may further include one or more line contacts 34 extending in the Y-direction in plan view. Each line contact 34 may extend at least between two opposite ends of the n⁺-type region 24 in the Y-direction in plan view. The line contact 34 may be arranged between two adjacent gate trenches 14. The line contact 34 may connect a contact region 48 (refer to FIG. 2) formed in the semiconductor layer 12 to the source interconnection 28. The line contact 34 may extend through the semiconductor layer 12 and the insulation layer 16 located between the contact region 48 and the source interconnection 28 in the Z-direction.

The semiconductor device 10 may further include one or more contacts 36 that connect the peripheral electrode 56 (refer to FIG. 4) arranged in the peripheral trench 18 to the source interconnection 28.

The gate contacts 30, the source contacts 32, the line contacts 34, and the contacts 36 may each be formed from any metal material. In an example, the contacts 30, 32, 34, and 36 may each be formed from at least one of tungsten (W), Ti, and titanium nitride (TiN).

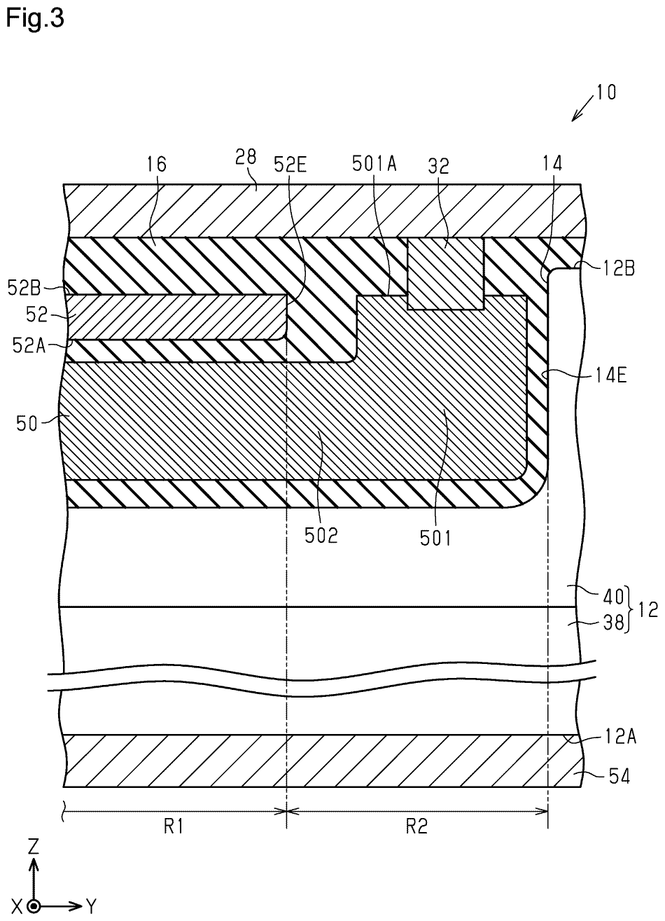

FIG. 2 is a schematic cross-sectional view of the semiconductor device 10 taken along line F2-F2 in FIG. 1. FIG. 2 shows a cross section of the gate trench 14 in a first region R1, which will be described later with reference to FIG. 3.

The semiconductor layer 12 may include a semiconductor substrate 38 and an epitaxial layer 40. The semiconductor substrate 38 includes the first surface 12A of the semiconductor layer 12. The epitaxial layer 40 is formed on the semiconductor substrate 38 and includes the second surface 12B of the semiconductor layer 12. The semiconductor substrate 38 may be a Si substrate. The semiconductor substrate 38 corresponds to a drain region of a MISFET. The epitaxial layer 40 may be a Si layer epitaxially grown on a Si substrate. The epitaxial layer 40 may include a drift region 42, a body region 44 formed on the drift region 42, and a source region 46 formed on the body region 44. The source region 46 may include the second surface 12B of the semiconductor layer 12. The upper surface of the source region 46 corresponds to the n⁺-type region 24 shown in FIG. 1. The epitaxial layer 40 may further include the contact region 48 located under the line contact 34.

A drain region 38 (semiconductor substrate 38) may be an n⁺-type region including an n-type impurity. The concentration of the n-type impurity in the drain region 38 may be in a range of 1×10¹⁸ cm⁻³ to 1×10²⁰ cm⁻³, inclusive. The drain region 38 may have a thickness in a range of 50 μm to 450 μm, inclusive.

The drift region 42 may be an n⁻-type region including an n-type impurity at a lower concentration than the drain region 38. The concentration of the n-type impurity in the drift region 42 may be in a range of 1× 10¹⁵ cm⁻³ to 1×10¹⁸ cm⁻³, inclusive. The drift region 42 may have a thickness in a range of 1 μm to 25 μm, inclusive.

The body region 44 may be a p⁻-type region including a p⁻-type impurity. The concentration of the p⁻-type impurity in the body region 44 may be in a range of 1× 10¹⁶ cm⁻³ to 1×10¹⁸ cm⁻³, inclusive. The body region 44 may have a thickness in a range of 0.5 μm to 1.5 μm, inclusive.

The source region 46 may be an n⁺-type region including an n-type impurity at a higher concentration than the drift region 42. The concentration of the n-type impurity in the source region 46 may be in a range of 1×10¹⁹ cm⁻³ to 1×10²¹ cm⁻³, inclusive. The source region 46 may have a thickness in a range of 0.1 μm to 1 μm, inclusive.

The contact region 48 may be a p⁺-type region including a p⁻-type impurity. The concentration of the p⁻-type impurity in the contact region 48 may be in a range of 1× 10¹⁹ cm⁻³ to 1×10²¹ cm⁻³, inclusive, which is higher than that of the body region 44.

In the present disclosure, n-type is also referred to as a first conductive type, and p-type is also referred to as a second conductive type. The n-type impurity may be, for example, phosphorus (P), arsenic (As), or the like. The p⁻-type impurity may be, for example, boron (B), aluminum (Al), or the like.

The gate trench 14 is open in the second surface 12B of the semiconductor layer 12. The gate trench 14 includes a side wall 14A and a bottom wall 14B. The bottom wall 14B is adjacent to the drift region 42. In other words, the gate trench 14 extends through the source region 46 and the body region 44 of the semiconductor layer 12 to the drift region 42. The gate trench 14 may have a depth D in a range of 1 μm to 10 μm, inclusive. The depth D of the gate trench 14 may be defined as a distance from the second surface 12B of the semiconductor layer 12 to the bottom wall 14B of the gate trench 14 (when bottom wall 14B is curved, the deepest part of gate trench 14) in the Z-direction.

The side wall 14A of the gate trench 14 may extend in a direction (Z-direction) orthogonal to the second surface 12B of the semiconductor layer 12. Alternatively, the side wall 14A of the gate trench 14 may be inclined with respect to the direction (Z-direction) orthogonal to the second surface 12B of the semiconductor layer 12. In an example, the side wall 14A may be inclined with respect to the Z-direction such that the gate trench 14 becomes narrower toward the bottom wall 14B. Furthermore, the bottom wall 14B of the gate trench 14 does not necessarily have to be flat and may be, for example, partially or entirely curved.

The semiconductor device 10 may further include the field plate electrode 50 and the gate electrode 52. The field plate electrode 50 is arranged in the gate trench 14 and has a width in the X-direction. The gate electrode 52 is arranged in the gate trench 14 and is separated from the field plate electrode 50 by the insulation layer 16. In the first region R1 (refer to FIG. 3), the gate electrode 52 is located above the field plate electrode 50 in the depth-wise direction of the gate trench 14.

The field plate electrode 50 is arranged in the gate trench 14 between the bottom wall 14B of the gate trench 14 and a bottom surface 52A of the gate electrode 52. The field plate electrode 50 is surrounded by the insulation layer 16. The field plate electrode 50 may have a smaller width than the gate electrode 52 in the X-direction. The field plate electrode 50 may be at the same potential as the source region 46. Source voltage may be applied to the field plate electrode 50 to reduce electric field concentration in the gate trench 14 and increase the breakdown voltage of the semiconductor device 10.

The field plate electrode 50 may have a uniform width regardless of the position in the Z-direction. Alternatively, the field plate electrode 50 may have a width that decreases toward the bottom wall 14B of the gate trench 14. Since the width of the gate trench 14 may decrease toward the bottom wall 14B, as described above, the width of the field plate electrode 50 may also decrease toward the bottom wall 14B.

In the present specification, the width of the field plate electrode 50 may refer to the width of the field plate electrode 50 at a specific depth position in the gate trench 14. In an example, the specific depth position of the gate trench 14 may be a position Pₐ in the depth-wise direction (position located below second surface 12B of semiconductor layer 12 by distance Da) at which the field plate electrode 50 has the largest width in the first region R1. In this case, the width of the field plate electrode 50 is W1ₐ shown in FIG. 2. In the example shown in FIG. 2, the field plate electrode 50 has the largest width at an upper surface 50A. Thus, it can also be said that W1ₐ is the width of the upper surface 50A. In another example, the specific depth position of the gate trench 14 may be a central position P_{half} in the depth-wise direction of the gate trench 14 (position located below second surface 12B of semiconductor layer 12 by half the depth D of gate trench 14). In this case, the width of the field plate electrode 50 is W1_{half} shown in FIG. 2.

The specific depth position of the gate trench 14 is not limited to the above examples and may be set to any depth that allows for an appropriate comparison between the width of the field plate electrode 50 in one region and the width of the field plate electrode 50 in another region.

The gate electrode 52 may include the bottom surface 52A that at least partially faces the field plate electrode 50, and the upper surface 52B that is located at the side opposite to the bottom surface 52A. The upper surface 52B of the gate electrode 52 may be located downward from the second surface 12B of the semiconductor layer 12. The bottom surface 52A and the upper surface 52B of the gate electrode 52 may be flat or curved. The gate electrode 52 may have a uniform width regardless of the position in the Z-direction. Alternatively, the width of the gate electrode 52 may vary in the Z-direction. For example, a bottom portion of the gate electrode 52, including the bottom surface 52A, may be narrower than the other portions.

The gate electrode 52 may be arranged such that the interface between the drift region 42 and the body region 44 is not located below the bottom surface 52A of the gate electrode 52 in the Z-direction. The interface between the drift region 42 and the body region 44 may be aligned with the bottom surface 52A of the gate electrode 52 in the Z-direction or may be located upward from the bottom surface 52A.

In an example, the field plate electrode 50 and the gate electrode 52 may be formed from a conductive polysilicon.

The insulation layer 16 may include a gate insulator 161 that is located between the gate electrode 52 and the semiconductor layer 12 and covers the side wall 14A of the gate trench 14. The gate insulator 161 separates the gate electrode 52 from the semiconductor layer 12. When a predetermined voltage is applied to the gate electrode 52, a channel is formed in the p⁻-type body region 44, which is adjacent to the gate insulator 161. The semiconductor device 10 allows for control of a flow of electrons in the Z-direction between the n⁺-type source region 46 and the n⁻-type drift region 42 through the channel.

The insulation layer 16 may further include a lower insulator 162 that is located between the field plate electrode 50 and the semiconductor layer 12 and covers the side wall 14A and the bottom wall 14B of the gate trench 14. The lower insulator 162 may be thicker than the gate insulator 161 on the side wall 14A of the gate trench 14. The insulation layer 16 may further include an intermediate insulator 163 that is located between the upper surface 50A of the field plate electrode 50 and the bottom surface 52A of the gate electrode 52.

In an example, the insulation layer 16 may be formed by a silicon dioxide (SiO₂) film. In addition to or instead of the silicon dioxide film, the insulation layer 16 may include a film formed from an insulative material that differs from SiO₂, for example, silicon nitride (SiN).

The semiconductor device 10 may further include a drain electrode 54 formed on the first surface 12A of the semiconductor layer 12. The drain electrode 54 is electrically connected to the drain region 38. The drain electrode 54 may be formed from at least one of Ti, Ni, Au, Ag, Cu, Al, a Cu alloy, and an Al alloy.

In the cross section shown in FIG. 2, the source interconnection 28 is formed on the insulation layer 16. The source interconnection 28 covers the insulation layer 16 and is electrically connected via the line contact 34 to the contact region 48.

FIG. 3 is a schematic cross-sectional view of the semiconductor device 10 taken along line F3-F3 in FIG. 1. FIG. 3 shows a cross section of part of the gate trench 14 including one end 14E of the gate trench 14.

The gate trench 14 may include the first region R1, in which the gate electrode 52 is located above the field plate electrode 50 in the Z-direction, and the second region R2 that includes the one end 14E of the gate trench 14 in the Y-direction. The gate electrode 52 arranged in the first region R1 does not extend into the second region R2. The second region R2 of the gate trench 14 may be located between the end 14E of the gate trench 14 and an end 52E of the gate electrode 52 in plan view (refer to FIG. 4, also).

In the first region R1, the field plate electrode 50 may be located below the gate electrode 52. The gate electrode 52 is connected via the gate contact 30 to the gate interconnection 26 in the first region R1 (refer to FIG. 1). In the second region R2, in contrast, the field plate electrode 50 may include an end portion 501 that extends upward from the bottom surface 52A of the gate electrode 52 for connection to the source contact 32. The field plate electrode 50 is connected via the source contact 32 to the source interconnection 28 in the second region R2. The end portion 501 of the field plate electrode 50 may include an upper surface 501A that is located above the bottom surface 52A of the gate electrode 52 in the Z-direction. In an example, the upper surface 501A of the end portion 501 may be aligned with the upper surface 52B of the gate electrode 52 in the Z-direction.

The field plate electrode 50 in the second region R2 may include an intermediate portion 502, in addition to the end portion 501. The intermediate portion 502 is continuous with the field plate electrode 50 located in the first region R1. The intermediate portion 502 may be located between the end 52E of the gate electrode 52 and the end portion 501 of the field plate electrode 50 in plan view. Instead of the gate electrode 52, the insulation layer 16 is present above the intermediate portion 502. The insulation layer 16 separates the gate electrode 52 from the end portion 501 of the field plate electrode 50.

In the present specification, a terminal end portion of the gate trench 14 may refer to a portion of the gate trench 14 that accommodates a widened portion of the field plate electrode 50 (end portion 501 in the present embodiment), and may include the end 14E of the gate trench 14. In the example shown in FIG. 3, the terminal end portion of the gate trench 14 may correspond to part of the second region R2 of the gate trench 14 that is located toward the end 14E.

FIG. 4 is an enlarged plan view of the semiconductor device 10. FIG. 4 shows a plan view of the semiconductor device 10 in an XY plane including the end portion 501 of the field plate electrode 50 (for example, upper surface 501A) and the gate electrode 52 (for example, upper surface 52B).

The gate electrode 52 is arranged in the first region R1. The field plate electrode 50 is also present in the first region R1. However, the field plate electrode 50 is located below the gate electrode 52 and thus cannot be seen in FIG. 4. The end portion 501 and the intermediate portion 502 of the field plate electrode 50 (refer to FIG. 3) are arranged in the second region R2. The intermediate portion 502 is located below the insulation layer 16 and thus cannot be seen in FIG. 4.

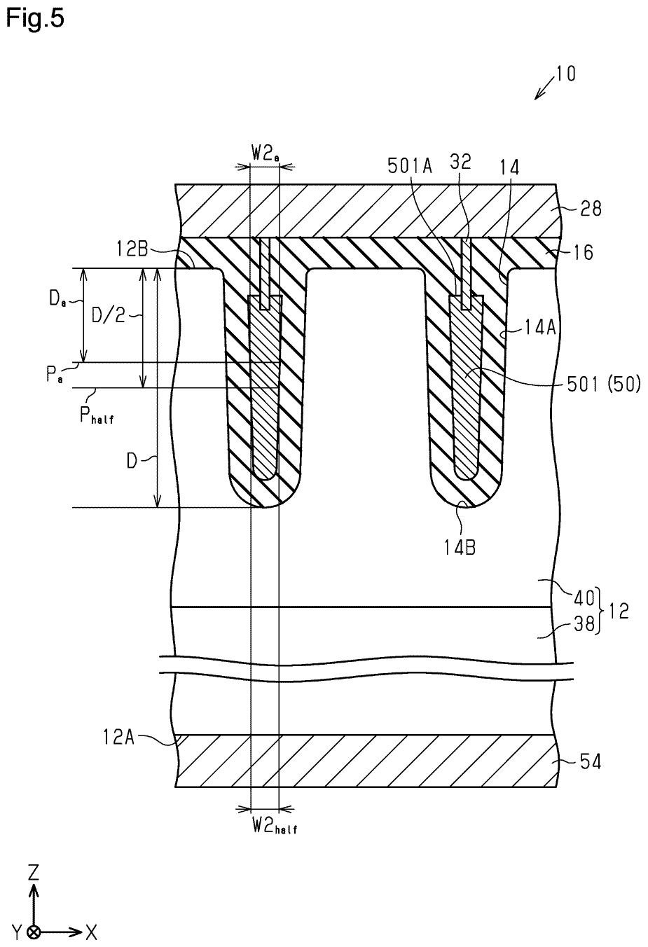

The width of the end portion 501 of the field plate electrode 50 in the second region R2, which will be described later with reference to FIG. 5, is greater than the width of the field plate electrode 50 in the first region R1. The end portion 501 may have a length in the Y-direction that is greater than six times the width of the end portion 501 in the X-direction.

The source contact 32 may be arranged on the end portion 501. In the example shown in FIG. 4, the source contact 32 may be located substantially at the center of the upper surface 501A of the end portion 501.

The semiconductor device 10 may further include the peripheral electrode 56 arranged in the peripheral trench 18. The peripheral electrode 56 may be embedded in the peripheral trench 18 via the insulation layer 16. As shown in FIG. 1, the peripheral trench 18 may have the form of a rectangular frame that surrounds the gate trenches 14. Thus, the peripheral electrode 56 may also have the form of a rectangular frame in correspondence with the shape of the peripheral trench 18. In the same manner as the field plate electrode 50, the peripheral electrode 56 may be formed from a conductive polysilicon.

FIG. 5 is a schematic cross-sectional view of the semiconductor device 10 taken along line F5-F5 in FIG. 4. FIG. 5 shows a cross section of the end portion 501 of the field plate electrode 50 in the second region R2 of the gate trench 14.

In the second region R2, the gate electrode 52 is not located above the field plate electrode 50. The end portion 501 of the field plate electrode 50 in the second region R2 extends upward to the vicinity of the opening of the gate trench 14. The end portion 501 of the field plate electrode 50 is connected via the source contact 32 to the source interconnection 28.

The width of the end portion 501 of the field plate electrode 50 in the second region R2 may be greater than the width of the field plate electrode 50 in the first region R1. In other words, the field plate electrode 50 in the second region R2 may include the end portion 501 that is wider than the field plate electrode 50 in the first region R1. In the example shown in FIG. 5, the end portion 501 may be referred to as a widened portion of the field plate electrode 50.

The width of the field plate electrode 50 in the first region R1 and the width of the end portion 501 may be compared at the same specific depth position of the gate trench 14. For example, when the specific depth position is the position Pₐ, which is described above with reference to FIG. 2 (position located below second surface 12B of semiconductor layer 12 by distance Da), the width of the end portion 501 at the position Pₐ is W2ₐ shown in FIG. 5. The width W2ₐ of the end portion 501 at the specific depth position Pₐ of the gate trench 14 is greater than the width W1ₐ of the field plate electrode 50 in the first region R1 (refer to FIG. 2).

In another example, the specific depth may be the position P_{half} (position located below second surface 12B of semiconductor layer 12 by half the depth D of gate trench 14). In this case, the width of the end portion 501 at the position P_{half} is W2_{half} shown in FIG. 5. The width W2_{half} of the end portion 501 at the specific depth position P_{half} of the gate trench 14 is greater than the width W1_{half} of the field plate electrode 50 in the first region R1 (refer to FIG. 2).

When the width of the field plate electrode 50 in the first region R1 and the width of the end portion 501 in the second region R2 are compared at a specific depth position of the gate trench 14, the end portion 501 is located at least at the specific depth position. In the example shown in FIG. 5, the width of the end portion 501 of the field plate electrode 50 in the second region R2 from the lower end to the upper end of the field plate electrode 50 (i.e., at any depth position) may be greater than the width of the field plate electrode 50 in the first region R1. Thus, the entire end portion 501 of the field plate electrode 50 in the second region R2 corresponds to the widened portion.

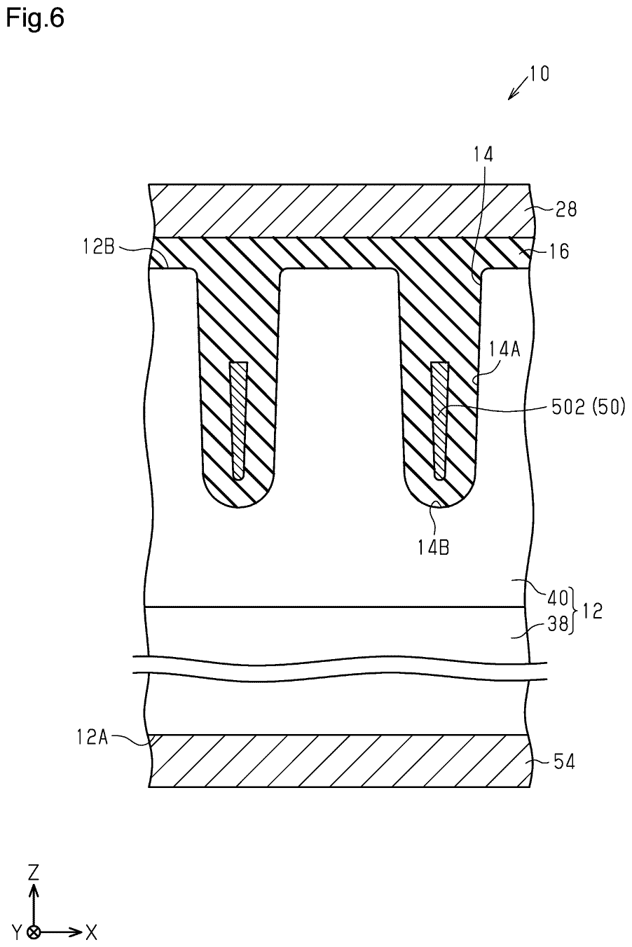

In the present embodiment, the width of the gate trench 14 in the first region R1 is substantially the same as the width of the gate trench 14 in the second region R2. Therefore, the insulation layer 16 located between the end portion 501 (widened portion) of the field plate electrode 50 and the side wall 14A in the second region R2 is thinner than the insulation layer 16 located between the field plate electrode 50 and the side wall 14A in the first region R1. In this case, the thickness of the insulation layer 16 located between the end portion 501 (widened portion) of the field plate electrode 50 and the side wall 14A in the second region R2 may be greater than 0.8 times the thickness of the insulation layer 16 located between the field plate electrode 50 and the side wall 14A in the first region R1. The thickness of the insulation layer 16 in different regions may be compared at the same specific depth position, in the same manner as the width of the field plate electrode 50. FIG. 6 is a schematic cross-sectional view of the semiconductor device 10 taken along line F6-F6 in FIG. 4. FIG. 6 shows a cross section of the intermediate portion 502 of the field plate electrode 50 in the second region R2 of the gate trench 14.

The intermediate portion 502 of the field plate electrode 50 in the second region R2 may have substantially the same cross section as the field plate electrode 50 in the first region R1 shown in FIG. 2. Thus, the width of the intermediate portion 502 in the second region R2 may be substantially the same as the width of the field plate electrode 50 in the first region R1 but less than the width of the end portion 501 in the second region R2. The insulation layer 16 is embedded above the intermediate portion 502.

### Operation

The operation of the semiconductor device 10 in accordance with the present embodiment will now be described.

In the semiconductor device 10 of the present embodiment, the field plate electrode 50 in the second region R2 includes the end portion 501 (widened portion) having a greater width than the field plate electrode 50 in the first region R1.

At a terminal end portion of the gate trench 14, growth of the insulation layer 16 from three directions may form an enclosure. This may result in a void in a region where the end portion 501 of the field plate electrode 50 is to be formed. Such a void hinders adequate formation of the field plate electrode 50 and reduces the effect of the field plate electrode 50 that expands a depletion layer in the semiconductor layer 12. Consequently, the breakdown voltage of the semiconductor device may be lowered.

In this respect, in the semiconductor device 10 of the present embodiment, the end portion 501 (widened portion) having a relatively large width is arranged on the field plate electrode 50 in the second region R2, which includes one end of the gate trench 14. Thus, even when the insulation layer 16 grows from three directions at the terminal end portion of the gate trench 14, the insulation layer 16 is less likely to form an enclosure.

### Advantages

The semiconductor device 10 of the present embodiment has the following advantages.

(1-1) The gate trench 14 includes the first region R1, in which the gate electrode 52 is located above the field plate electrode 50 in the depth-wise direction of the gate trench 14, and the second region R2 that includes one end of the gate trench 14 in the first direction (Y-direction). The field plate electrode 50 in the second region R2 includes the end portion 501 (widened portion) that has a greater width than the field plate electrode 50 in the first region R1. This structure avoids formation of a void in the gate trench 14.

(1-2) The thickness of the insulation layer 16 located between the end portion 501 (widened portion) of the field plate electrode 50 and the side wall 14A in the second region R2 may be greater than 0.8 times the thickness of the insulation layer 16 located between the field plate electrode 50 and the side wall 14A in the first region R1. This structure avoids a situation in which the breakdown voltage is lowered by an excessively thin insulation layer 16 located adjacent to the end portion 501 (widened portion) of the field plate electrode 50.

(1-3) The end portion 501 of the field plate electrode 50 may have a length in the Y-direction that is greater than six times the width of the end portion 501. This structure avoids a situation in which embedding of the field plate electrode 50 becomes difficult due to the end portion 501 that is short in the Y-direction.

### Modified Example of First Embodiment

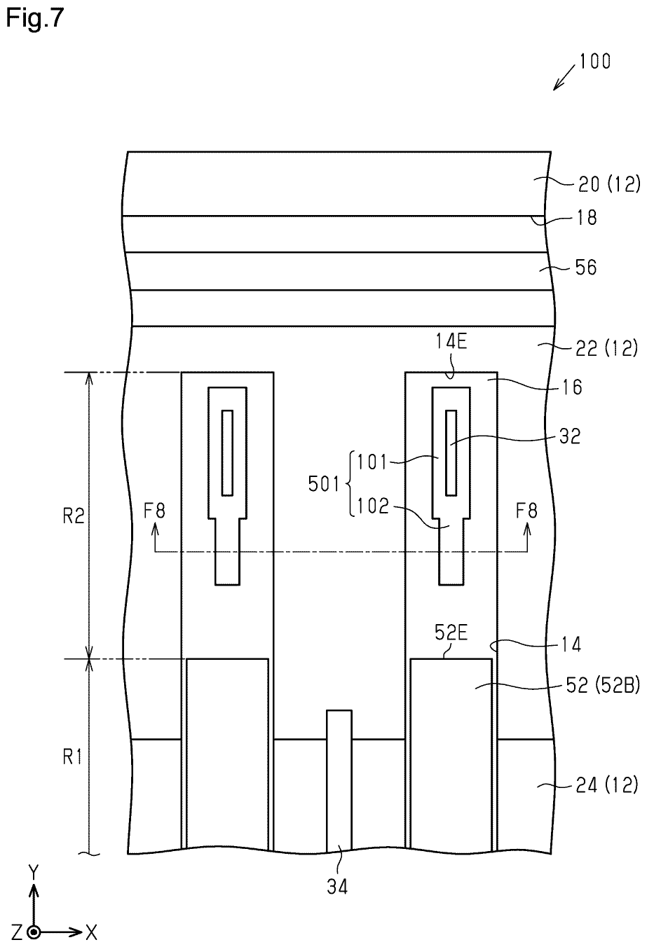

FIG. 7 is an enlarged plan view of a semiconductor device 100 in accordance with a modified example of the first embodiment. In FIG. 7, same reference characters are given to those elements that are the same as the corresponding elements of the semiconductor device 10. Such elements will not be described in detail.

The semiconductor device 100 differs from the semiconductor device 10 in that the end portion 501 of the field plate electrode 50 in the second region R2 includes a first part 101 and a second part 102 that has a smaller width than the first part 101. The second part 102 is located between the first part 101 and the gate electrode 52 in plan view.

The first part 101 is wider than the field plate electrode 50 in the first region R1. In the example shown in FIG. 7, the first part 101 may be referred to as a widened portion of the field plate electrode 50. The first part 101 (widened portion) shown in FIG. 7 may have a cross section that is substantially the same as the cross-section of the end portion 501 shown in FIG. 5.

The first part 101 may have a length in the Y-direction that is greater than six times the width of the first part 101 in the X-direction. This facilitates embedding of the first part 101 of the field plate electrode 50.

The second part 102 may have a smaller width than the first part 101. In an example, the second part 102 may have substantially the same width as the field plate electrode 50 in the first region R1. The second part 102 may have a length that is greater than 1 μm in the Y-direction. The second part 102 allows the first part 101, which is the widened portion, to be located relatively far from the first region R1. This avoids variations in the breakdown voltage of the semiconductor device 100.

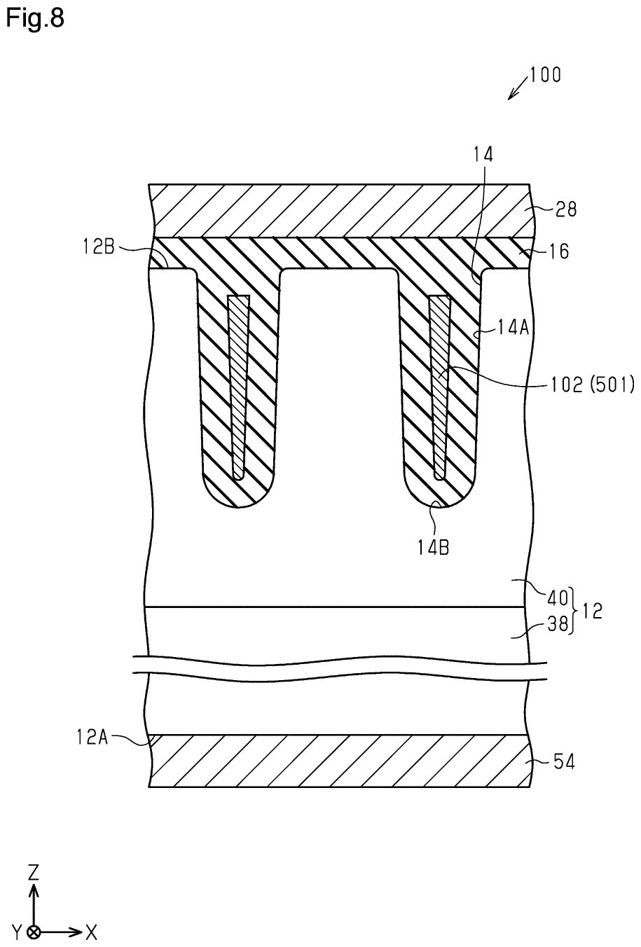

In an example, the insulation layer 16 located between the first part 101 of the field plate electrode 50 and the side wall 14A (refer to FIG. 5) may have a thickness that is greater than 0.8 times the thickness of the insulation layer 16 located between the second part 102 of the field plate electrode 50 and the side wall 14A (refer to FIG. 8). This avoids a situation in which the breakdown voltage is lowered by an excessively thin insulation layer 16 located adjacent to the first part 101 (widened portion) of the field plate electrode 50.

As shown in FIG. 7, the source contact 32 may be arranged on the first part 101. In this case, the source contact 32 may be located substantially at the center of the first part 101 in plan view. In another example, the source contact 32 may be arranged across the boundary between the first part 101 and the second part 102.

FIG. 8 is a schematic cross-sectional view of the semiconductor device 100 taken along line F8-F8 in FIG. 7. FIG. 8 shows an XZ cross section of the second part 102 of the field plate electrode 50 in the second region R2 of the gate trench 14.

In the same manner as the first part 101, the second part 102 extends upward to the vicinity of the opening of the gate trench 14. However, the second part 102 has a smaller width than the first part 101. In an example, the second part 102 may have substantially the same width as the field plate electrode 50) in the first region R1 (refer to FIG. 2). As apparent from FIGS. 2 and 8, the second part 102 has a dimension in the Z-direction that differs from that of the field plate electrode 50 in the first region R1. Nonetheless, the second part 102 may have substantially the same width as the field plate electrode 50 in the first region R1 at a specific depth position in the gate trench 14, where at least the field plate electrode 50 is arranged in the first region R1.

The semiconductor device 100 has the same advantages as the semiconductor device 10. In addition, in the semiconductor device 100, the field plate electrode 50 in the second region R2 includes the second part 102 having a smaller width than the first part 101. In plan view, the second part 102 is located between the first part 101 and the gate electrode 52. With this structure, the first part 101, which is the widened portion, is located relatively far from the first region R1. Thus, the breakdown voltage of the semiconductor device 100 will not be varied by the difference in the width of the field plate electrode 50 near the first region R1.

### Second Embodiment

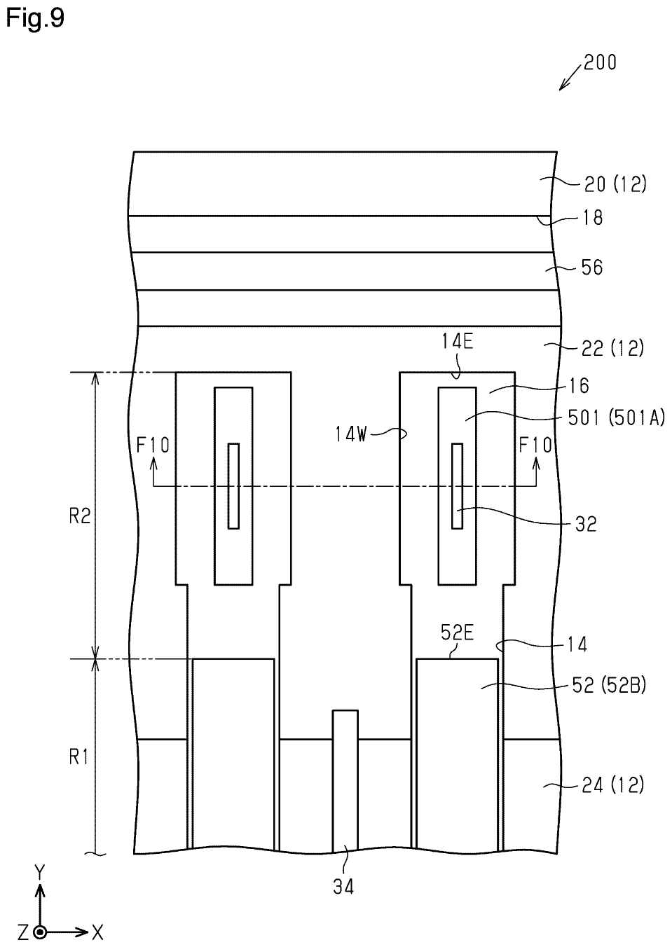

FIG. 9 is an enlarged plan view of a semiconductor device 200 in accordance with a second embodiment. In FIG. 9, same reference characters are given to those elements that are the same as the corresponding elements of the semiconductor device 10. Such elements will not be described in detail.

In the semiconductor device 200, the gate trench 14 in the second region R2 includes a portion 14W that accommodates at least the end portion 501 (widened portion) of the field plate electrode 50. The portion 14W has a width that is greater than the width of the gate trench 14 in the first region R1. The portion 14W of the gate trench 14, which is wider than the gate trench 14 in the first region R1, may include the end 14E of the gate trench 14.

In the gate trench 14 in the second region R2, the portion 14W accommodating at least the end portion 501 (widened portion) may have a width that is greater than or equal to 1.1 times the width of the gate trench 14 in the first region R1 and less than 1.5 times the width of the gate trench 14 in the first region R1. In contrast, in the gate trench 14 in the second region R2, a portion accommodating the intermediate portion 502 (refer to FIG. 3) may have the same width as the gate trench 14 in the first region R1.

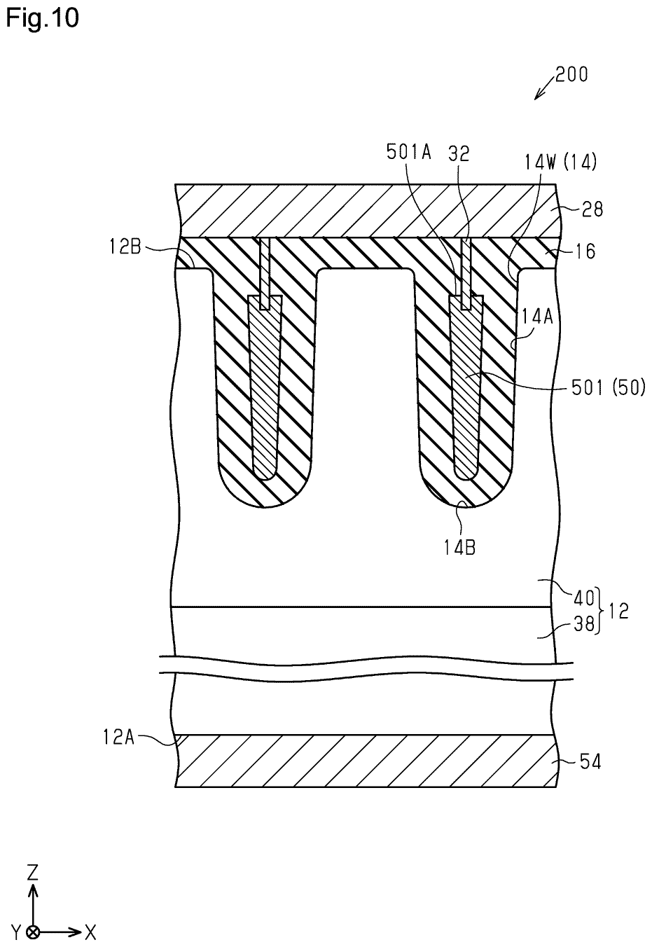

FIG. 10 is a schematic cross-sectional view of the semiconductor device 200 taken along line F10-F10 in FIG. 9. FIG. 10 shows an XZ cross section of the portion 14W of the gate trench 14 that accommodates the end portion 501. The portion 14W of the gate trench 14 accommodating the end portion 501 is wider than the gate trench 14 in the first region R1 (refer to FIG. 2). Therefore, in the semiconductor device 200, the thickness of the insulation layer 16 located between the end portion 501 (widened portion) of the field plate electrode 50 and the side wall 14A is greater than that in the semiconductor device 10 (refer to FIG. 5). The thickness of the insulation layer 16 located between the end portion 501 (widened portion) of the field plate electrode 50 and the side wall 14A in the second region R2 does not necessarily have to be less than the thickness of the insulation layer 16 located between the field plate electrode 50 and the side wall 14A in the first region R1 in the same manner as the first embodiment. In the semiconductor device 200, the thickness of the insulation layer 16 located between the end portion 501 (widened portion) of the field plate electrode 50 and the side wall 14A in the second region R2 may be the same as or greater than the thickness of the insulation layer 16 located between the field plate electrode 50 and the side wall 14A in the first region R1. The thickness of the insulation layer 16 located between the field plate electrode 50 and the side wall 14A in different regions may be compared at the same specific depth position.

### Operation

The operation of the semiconductor device 200 in accordance with the present embodiment will now be described.

In the semiconductor device 200 of the present embodiment, the field plate electrode 50 in the second region R2 includes the end portion 501 (widened portion) having a greater width than the field plate electrode 50 in the first region R1. Further, the gate trench 14 in the second region R2 includes the portion 14W that accommodates at least the end portion 501 (widened portion) of the field plate electrode 50. The portion 14W has a width that is greater than the width of the gate trench 14 in the first region R1.

At a terminal end portion of the gate trench 14, growth of the insulation layer 16 from three directions may form an enclosure. This may result in a void in a region where the end portion 501 of the field plate electrode 50 is to be formed. Such a void hinders adequate formation of the field plate electrode 50 and reduces the effect of the field plate electrode 50 that expands a depletion layer in the semiconductor layer 12. Consequently, the breakdown voltage of the semiconductor device may be lowered.

In this respect, in the semiconductor device 200 of the present embodiment, the end portion 501 (widened portion) having a relatively large width is arranged on the field plate electrode 50 in the second region R2, which includes one end of the gate trench 14. Further, in the gate trench 14 in the second region R2, the portion 14W, which accommodates at least the end portion 501 (widened portion) of the field plate electrode 50, is relatively wide. Thus, even when the insulation layer 16 grows from three directions at the terminal end portion of the gate trench 14, the insulation layer 16 is even less likely to form an enclosure.

Furthermore, in the semiconductor device 200, the thickness of the insulation layer 16 located between the end portion 501 of the field plate electrode 50 and the side wall 14A of the gate trench 14 may be greater than that in the first embodiment. This avoids a decrease in the breakdown voltage of the semiconductor device 200.

### Advantages

The semiconductor device 200 of the present embodiment has the following advantages in addition to advantages (1-1) to (1-3) of the semiconductor device 10 described above.

(2-1) The gate trench 14 in the second region R2 includes the portion 14W that accommodates at least the end portion 501 (widened portion) of the field plate electrode 50. The portion 14W has a width that is greater than the width of the gate trench 14 in the first region R1. This structure further avoids formation of a void in the gate trench 14.

(2-2) In the gate trench 14 in the second region R2, the portion 14W that accommodates at least the end portion 501 (widened portion) may have a width that is greater than or equal to 1.1 times the width of the gate trench 14 in the first region R1 and less than 1.5 times the width of the gate trench 14 in the first region R1. This structure avoids a decrease in the breakdown voltage of the semiconductor device 200 while ensuring a suitable thickness of the insulation layer 16 located between the end portion 501 (widened portion) of the field plate electrode 50 and the side wall 14A without excessively decreasing the distance between the gate trenches 14.

### Modified Example of Second Embodiment

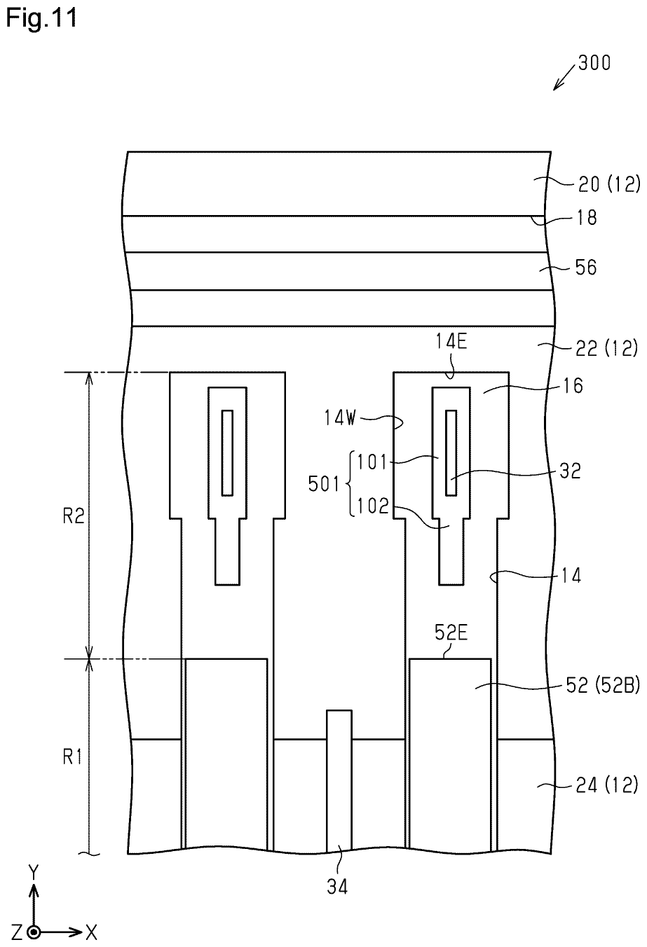

FIG. 11 is an enlarged plan view of a semiconductor device 300 in accordance with a modified example of the second embodiment. In FIG. 11, same reference characters are given to those elements that are the same as the corresponding elements of the semiconductor device 200. Such elements will not be described in detail.

The semiconductor device 300 differs from the semiconductor device 200 in that the end portion 501 of the field plate electrode 50 in the second region R2 includes the first part 101 and the second part 102 that has a smaller width than the first part 101. The second part 102 is located between the first part 101 and the gate electrode 52 in plan view. In the semiconductor device 300, the gate trench 14 in the second region R2 includes the portion 14W that accommodates at least the first part 101. The portion 14W has a width that is greater than the width of the gate trench 14 in the first region R1.

The first part 101 is wider than the field plate electrode 50 in the first region R1. In the example shown in FIG. 11, the first part 101 may be referred to as a widened portion of the field plate electrode 50. The first part 101 (widened portion) shown in FIG. 11 may have a cross section that is the same as the cross-section of the end portion 501 shown in FIG. 10.

The first part 101 may have a length in the Y-direction that is greater than six times the width of the first part 101 in the X-direction. This facilitates embedding of the first part 101 of the field plate electrode 50.

The second part 102 may have a smaller width than the first part 101. In an example, the second part 102 may have substantially the same width as the field plate electrode 50 in the first region R1. The second part 102 shown in FIG. 11 may have a cross section that is the same as the cross section of the second part 102 shown in FIG. 8. The second part 102 may have a length that is greater than 1 μm in the Y-direction. The second part 102 allows the first part 101, which is the widened portion, to be located relatively far from the first region R1. This avoids variations in the breakdown voltage of the semiconductor device 300.

Accordingly, in the semiconductor device 300, the first part 101 corresponds to the widened portion of the field plate electrode 50 in the second region R2. Further, in the gate trench 14 in the second region R2, the portion 14W, which accommodates at least the first part 101 (widened portion), has a width that is greater than the width of the gate trench 14 in the first region R1. In contrast, in the gate trench 14 in the second region R2, a portion that accommodates the second part 102 may have the same width as the gate trench 14 in the first region R1.

In this manner, the portion 14W of the gate trench 14 having a relatively large width accommodates the first part 101 having a relatively large width, and the portion of the gate trench 14 having a relatively small width accommodates the second part 102 having a relatively small width. This reduces the difference between the thickness of the insulation layer 16 located between the first part 101 of the field plate electrode 50 and the side wall 14A (refer to FIG. 10) and the thickness of the insulation layer 16 located between the second part 102 of the field plate electrode 50 and the side wall 14A (refer to FIG. 8).

As shown in FIG. 11, the source contact 32 may be arranged on the first part 101. In this case, the source contact 32 may be located substantially at the center of the first part 101 in plan view. In another example, the source contact 32 may be arranged across the boundary between the first part 101 and the second part 102.

The semiconductor device 300 has the same advantages as the semiconductor device 200. In addition, in the semiconductor device 300, the field plate electrode 50 in the second region R2 includes the second part 102 having a smaller width than the first part 101. In plan view, the second part 102 is located between the first part 101 and the gate electrode 52. With this structure, the breakdown voltage of the semiconductor device 300 will not be varied by the difference in the width of the field plate electrode 50 near the first region R1.

### Modified Example of Cross-Sectional Shape of Field Plate Electrode in First Region

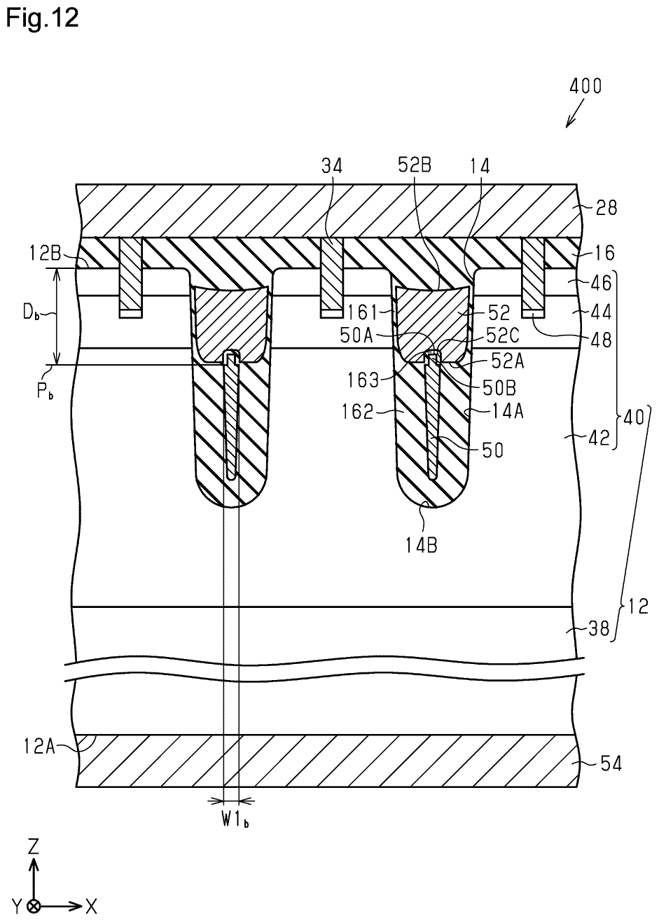

FIG. 12 is a schematic cross-sectional view of a semiconductor device 400 illustrating a modified example of a cross-sectional shape of the field plate electrode 50 in the first region R1.

The semiconductor device 400 shown in FIG. 12 differs from the semiconductor device 10 shown in FIG. 2 in that the upper surface 50A of the field plate electrode 50 is located upward from the bottom surface 52A of the gate electrode 52. The gate electrode 52 of the semiconductor device 400 includes a recess 52C formed in the bottom surface 52A. Further, the field plate electrode 50 includes an upper part 50B arranged in the recess 52C. The upper part 50B of the field plate electrode 50 located in the recess 52C of the gate electrode 52 has a smaller width than the other parts of the field plate electrode 50 located outside the recess 52C. Therefore, the semiconductor device 400 differs from the semiconductor device 10 in that the upper surface 50A of the field plate electrode 50 is not located at a position P_{b} where the field plate electrode 50 in the first region R1 has the largest width W1_{b} in the depth-wise direction. In FIG. 12, the position P_{b} is located below the second surface 12B of the semiconductor layer 12 by a distance D_{b}.

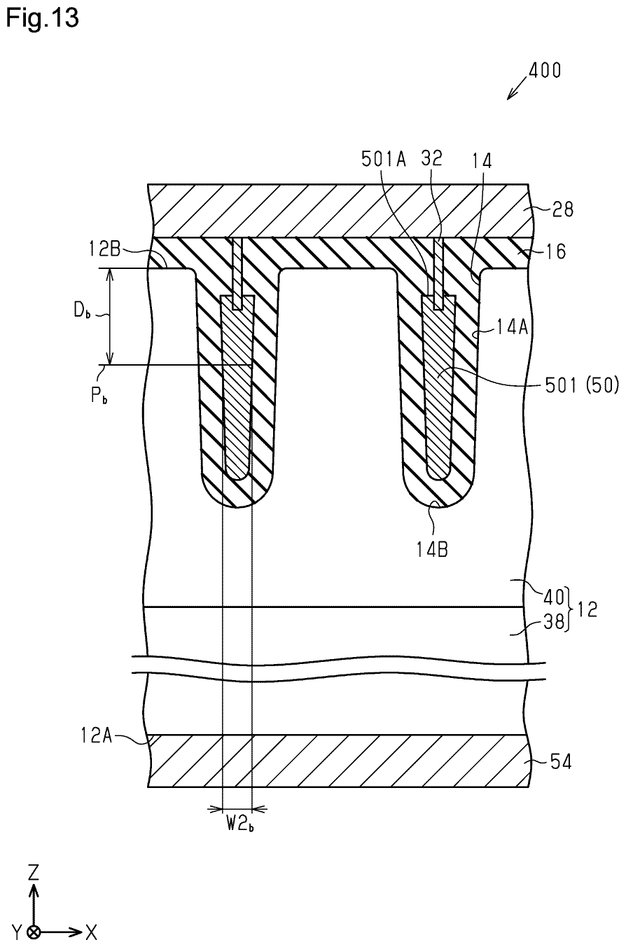

FIG. 13 is a schematic cross-sectional view of the semiconductor device 400 in the second region R2. The field plate electrode 50 in the second region R2 includes the end portion 501 (widened portion) that has a greater width than the field plate electrode 50 in the first region R1. At the position P_{b} in the depth-wise direction (position located below second surface 12B of semiconductor layer 12 by distance D_{b}), where the field plate electrode 50 in the first region R1 has the largest width W1_{b}, the width of the end portion 501 is W2_{b} shown in FIG. 13. At the specific depth position P_{b}, the width W2_{b} of the end portion 501 is greater than the width W1_{b} of the field plate electrode 50 in the first region R1 (refer to FIG. 12). Thus, even when the field plate electrode 50 has a cross-sectional shape differing from that of the semiconductor device 10, the width of the field plate electrode 50 in different regions may be compared at an appropriate specific depth position of the gate trench 14.

### Other Modified Examples

The embodiments and modified examples described above may be further modified as follows.

The specific depth position in the gate trench 14 may be a position located below the second surface 12B of the semiconductor layer 12 by two-thirds of the depth D of the gate trench 14.

The peripheral trench 18 does not have to be one trench having the form of a rectangular frame and may be two straight trenches arranged at opposite sides of the plurality of gate trenches 14.

Another interconnection structure may be formed on the layer including the gate interconnection 26 and the source interconnection 28.

In the semiconductor device 300 shown in FIG. 11, the second part 102 of the field plate electrode 50 may be partially accommodated in the portion 14W of the gate trench 14, which is wider than the gate trench 14 in the first region R1.

The depth D of the gate trench 14 may be changed in accordance with the width. Even in this case, the width of the field plate electrode 50 in different regions may be compared at a specific depth position determined by a distance from the second surface 12B of the semiconductor layer 12.

In each of the above embodiments, the conductivity type of each region in the semiconductor layer 12 may be reversed. Specifically, a p-type region may be changed to an n-type region, and an n-type region may be changed to a p-type region.

Various examples described in this specification may be combined as long as there is no technical contradiction.

In this specification, “at least one of A and B” should be understood to mean “only A, or only B, or both A and B.”

The word “on” used in this specification includes the meaning of “above” in addition to the meaning of “on” unless otherwise described in the context. Accordingly, the phrase “first layer formed on second layer” may mean that the first layer is formed directly contacting the second layer in one embodiment and that the first layer is located above the second layer without contacting the second layer in another embodiment. Thus, the word “on” will also allow for a structure in which another layer is formed between the first layer and the second layer.

The terms used in this specification to indicate directions, such as “vertical”, “horizontal”, “upward”, “downward”, “up”, “down”, “forward”, “rearward”, “lateral”, “side”, “left”, “right”, “front”, and “back”, will be attributed to specific directions of the device being described and illustrated. In the present disclosure, a variety of alternative directions may be available for any given direction. Thus, directional terms should not be construed narrowly.

In an example, the Z-axis direction referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification are not limited to upward and downward in the vertical direction. For example, the X-axis direction may be the vertical direction. Alternatively, the Y-axis direction may be the vertical direction.

### Clauses

Technical concepts that can be understood from the present disclosure will now be described. Reference characters used in the described embodiments are added to corresponding elements in the clauses to aid understanding without any intention to impose limitations on these elements. The reference characters are given as examples to facilitate understanding and not intended to limit elements to the elements denoted by the reference characters.

### [Clause 1]

A semiconductor device, including:
a semiconductor layer (12);
a gate trench (14) formed in the semiconductor layer (12), the gate trench (14) extending in a first direction in plan view and having a width in a second direction orthogonal to the first direction in plan view;
an insulation layer (16) formed on the semiconductor layer (12);
a field plate electrode (50) arranged in the gate trench (14) and having a width in the second direction; and
a gate electrode (52) arranged in the gate trench (14) and separated from the field plate electrode (50) by the insulation layer (16), in which:
the gate trench (14) includes
   a first region (R1) in which the gate electrode (52) is located above the field plate electrode (50) in a depth-wise direction of the gate trench (14), and
   a second region (R2) including an end (14E) of the gate trench (14) in the first direction; and
the field plate electrode (50) in the second region (R2) includes a widened portion (501, 101) having a width (W2) that is greater than a width (W1) of the field plate electrode (50) in the first region (R1).

### [Clause 2]

The semiconductor device according to clause 1, in which:
the widened portion (501, 101) is arranged at least at a specific depth position (Pₐ, P_{b}, P_{half}) in the gate trench (14); and
at the specific depth position (Pₐ, P_{b}, P_{half}), the width (W2ₐ, W2_{b}, W2_{half}) of the widened portion (501, 101) is greater than the width (W1ₐ, W1_{b}, W1_{half}) of the field plate electrode (50) in the first region (R1).

### [Clause 3]

The semiconductor device according to clause 2, in which the specific depth position (Pₐ, P_{b}, P_{half}) is a position (Pₐ, P_{b}) in the depth-wise direction at which the field plate electrode (50) in the first region (R1) has a largest width.

### [Clause 4]

The semiconductor device according to clause 2, in which the specific depth position (Pₐ, P_{b}, P_{half}) is a central position (P_{half}) of the gate trench (14) in the depth-wise direction.

### [Clause 5]

The semiconductor device according to any one of clauses 1 to 4, in which the insulation layer (16) located between the widened portion (501, 101) and a side wall (14A) of the gate trench (14) has a thickness that is greater than 0.8 times a thickness of the insulation layer (16) located between the field plate electrode (50) and the side wall (14A) in the first region (R1).

### [Clause 6]

The semiconductor device according to any one of clauses 1 to 5, in which the widened portion (501, 101) has a length in the first direction that is greater than six times the width of the widened portion (501, 101).

### [Clause 7]

The semiconductor device according to any one of clauses 1 to 6, in which the gate trench (14) in the second region (R2) includes a portion (14W) that accommodates at least the widened portion (501, 101), the portion (14W) having a width that is greater than a width of the gate trench (14) in the first region (R1).

### [Clause 8]

The semiconductor device according to any one of clauses 1 to 7, in which the gate trench (14) in the second region (R2) includes a portion (14W) that accommodates at least the widened portion (501, 101), the portion (14W) having a width that is greater than or equal to 1.1 times a width of the gate trench (14) in the first region (R1) and less than 1.5 times the width of the gate trench (14) in the first region (R1).

### [Clause 9]

The semiconductor device according to any one of clauses 1 to 8, in which:
the field plate electrode (50) in the second region (R2) includes a first part (101) corresponding to the widened portion (101), and a second part (102) having a smaller width than the first part (101); and
the second part (102) is located between the first part (101) and the gate electrode (52) in plan view.

### [Clause 10]

The semiconductor device according to clause 9, in which the width of the second part (102) is equal to the width of the field plate electrode (50) in the first region (R1).

### [Clause 11]

The semiconductor device according to clause 9 or 10, in which the gate trench (14) in the second region (R2) includes a portion that accommodates the second part (102), the portion having a width that is equal to a width of the gate trench (14) in the first region (R1).

### [Clause 12]

The semiconductor device according to any one of clauses 9 to 11, in which the second part (102) has a length that is greater than 1 μm in the first direction.

### [Clause 13]

The semiconductor device according to any one of clauses 9 to 12, in which the insulation layer (16) located between a side wall (14A) of the gate trench (14) and the first part (101) has a thickness that is greater than 0.8 times a thickness of the insulation layer (16) located between the side wall (14A) of the gate trench (14) and the second part (102).

### [Clause 14]

The semiconductor device according to any one of clauses 1 to 13, in which the field plate electrode (50) in the second region (R2) includes an upper surface (501A) that is located above a bottom surface of the gate electrode (52) in the first region (R1) in the depth-wise direction.

### [Clause 15]

The semiconductor device according to any one of clauses 1 to 14, further including:
a gate interconnection (26) formed on the insulation layer (16); and
a source interconnection (28) formed on the insulation layer (16) and separated from the gate interconnection (26), in which:
the gate electrode (52) is connected to the gate interconnection (26) in the first region (R1); and
the field plate electrode (50) is connected to the source interconnection (28) in the second region (R2).

### [Clause 16]

The semiconductor device according to clause 15, further including:
a source contact (32) that connects the field plate electrode (50) to the source interconnection (28) in the second region (R2), in which the source contact (32) is arranged on the widened portion (501, 101).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A semiconductor device, comprising:
a semiconductor layer;
a gate trench formed in the semiconductor layer, the gate trench extending in a first direction in plan view and having a width in a second direction orthogonal to the first direction in plan view;
an insulation layer formed on the semiconductor layer;
a field plate electrode arranged in the gate trench and having a width in the second direction; and
a gate electrode arranged in the gate trench and separated from the field plate electrode by the insulation layer, wherein:
the gate trench includes
a first region in which the gate electrode is located above the field plate electrode in a depth-wise direction of the gate trench, and
a second region including an end of the gate trench in the first direction; and
the field plate electrode in the second region includes a widened portion having a width that is greater than a width of the field plate electrode in the first region.

2. The semiconductor device according to claim 1, wherein:
the widened portion is arranged at least at a specific depth position in the gate trench; and
at the specific depth position, the width of the widened portion is greater than the width of the field plate electrode in the first region.

3. The semiconductor device according to claim 2, wherein the specific depth position is a position in the depth-wise direction at which the field plate electrode in the first region has a largest width.

4. The semiconductor device according to claim 2, wherein the specific depth position is a central position of the gate trench in the depth-wise direction.

5. The semiconductor device according to claim 1, wherein the insulation layer located between the widened portion and a side wall of the gate trench has a thickness that is greater than 0.8 times a thickness of the insulation layer located between the field plate electrode and the side wall in the first region.

6. The semiconductor device according to claim 1, wherein the widened portion has a length in the first direction that is greater than six times the width of the widened portion.

7. The semiconductor device according to claim 1, wherein the gate trench in the second region includes a portion that accommodates at least the widened portion, the portion having a width that is greater than a width of the gate trench in the first region.

8. The semiconductor device according to claim 1, wherein the gate trench in the second region includes a portion that accommodates at least the widened portion, the portion having a width that is greater than or equal to 1.1 times a width of the gate trench in the first region and less than 1.5 times the width of the gate trench in the first region.

9. The semiconductor device according to claim 1, wherein:
the field plate electrode in the second region includes a first part corresponding to the widened portion, and a second part having a smaller width than the first part; and
the second part is located between the first part and the gate electrode in plan view.

10. The semiconductor device according to claim 9, wherein the width of the second part is equal to the width of the field plate electrode in the first region.

11. The semiconductor device according to claim 9, wherein the gate trench in the second region includes a portion that accommodates the second part, the portion having a width that is equal to a width of the gate trench in the first region.

12. The semiconductor device according to claim 9, wherein the second part has a length that is greater than 1 μm in the first direction.

13. The semiconductor device according to claim 9, wherein the insulation layer located between a side wall of the gate trench and the first part has a thickness that is greater than 0.8 times a thickness of the insulation layer located between the side wall of the gate trench and the second part.

14. The semiconductor device according to claim 1, wherein the field plate electrode in the second region includes an upper surface that is located above a bottom surface of the gate electrode in the first region in the depth-wise direction.

15. The semiconductor device according to claim 1, further comprising:
a gate interconnection formed on the insulation layer, and
a source interconnection formed on the insulation layer and separated from the gate interconnection, wherein:
the gate electrode is connected to the gate interconnection in the first region; and
the field plate electrode is connected to the source interconnection in the second region.
